(19) United States
(12) Patent Application Publication
(10) Pub. No.: US 2025/0221092 A1
(43) Pub. Date: Jul. 3, 2025

(54) METHOD FOR FABRICATING DISPLAY DEVICE

(71) Applicant: Samsung Display Co., LTD., Yongin-si (KR)

(72) Inventor: Jeong Won HAN, Yongin-si (KR)

(73) Assignee: Samsung Display Co., LTD., Yongin-si (KR)

(21) Appl. No.: 18/772,830

(22) Filed: Jul. 15, 2024

(30) Foreign Application Priority Data
Dec. 29, 2023 (KR) 10-2023-0197302

(51) Int. Cl. H01L 33/00; H01L 25/075

(52) U.S. Cl. CPC H10H 20/01; H01L 25/0753; H10H 20/032

(57) ABSTRACT

A method of fabricating a display device includes preparing a target substrate and light-emitting elements, applying ink on the target substrate, supplying the light-emitting elements to the ink, and aligning the light-emitting elements to aligned positions on the target substrate. Accordingly, the alignment of the light-emitting elements is improved and the utilization efficiency of the light-emitting elements is increased.

### CROSS-REFERENCE TO RELATED APPLICATION(S)

This application claims priority to and the benefit of Korean Patent Application No. 10-2023-0197302 under 35 USC § 119, filed on Dec. 29, 2023, in the Korean Intellectual Property Office, the contents of which are incorporated herein by reference in its entirety.

### BACKGROUND

### 1. Technical Field

Embodiments of the disclosure relate to a method for fabricating a display device.

### 2. Description of the Related Art

Display devices for displaying images become more and more important as multimedia technology evolves. Accordingly, a variety of types of display devices, including light-emitting display devices, are under development. A light-emitting display device includes pixels including light-emitting elements.

### SUMMARY

Aspects of the disclosure relate to a method of fabricating a display device that can improve the alignment of light-emitting elements.

However, the disclosure is not restricted to the one set forth herein. The above and other aspects of the disclosure will become more apparent to one of ordinary skill in the art to which the disclosure pertains by referencing the detailed description of the disclosure given below.

According to an aspect of the disclosure, there is provided a method of fabricating a display device. The method may include preparing a target substrate and light-emitting elements, applying ink on the target substrate, supplying the light-emitting elements to the ink, and aligning the light-emitting elements to aligned positions on the target substrate.

In an embodiment, the preparing the light-emitting elements may include preparing a light-emitting element substrate including a semiconductor substrate and light-emitting elements formed in a rod shape on the semiconductor substrate, and the light-emitting elements may be prepared to be connected to each other through the semiconductor substrate.

In an embodiment, the supplying the light-emitting elements to the ink may include placing the light-emitting element substrate above the target substrate so that the light-emitting elements face the ink, and separating the light-emitting elements from the semiconductor substrate and dropping the light-emitting elements into the ink on the target substrate.

In an embodiment, the separating of the light-emitting elements from the semiconductor substrate may include using a cutting unit including a knife to separate the light-emitting elements from the semiconductor substrate.

In an embodiment, the separating of the light-emitting elements from the semiconductor substrate may include irradiating the light-emitting element substrate with a laser beam to separate the light-emitting elements from the semiconductor substrate.

In an embodiment, the ink may be prepared without contacting the light-emitting elements and applied on the target substrate prior to the light-emitting elements.

In an embodiment, the target substrate may include a base substrate and alignment electrodes disposed on the base substrate.

In an embodiment, the aligning of the light-emitting elements on the target substrate may include applying an alignment signal to the alignment electrodes to align the light-emitting elements between the alignment electrodes.

In an embodiment, the alignment signal may be applied to the alignment electrodes after the supplying of the light-emitting elements to the ink.

In an embodiment, the light-emitting elements may be supplied to the ink while the alignment signal is being applied to the alignment electrodes.

In an embodiment, the target substrate may include a base substrate and a bank disposed on the base substrate to define emission areas.

In an embodiment, the method may further include placing a mask including openings corresponding to the emission areas on the bank prior to the supplying of the light-emitting elements to the ink.

In an embodiment, the mask may be placed on the target substrate prior to the applying of the ink on the target substrate.

In an embodiment, the mask may be placed on the target substrate after the applying of the ink on the target substrate.

In an embodiment, the mask may be fixed on the target substrate by placing a mask holder on a stage supporting the target substrate.

In an embodiment, the mask may include a metal pattern, and the mask holder may include an electrostatic chuck or a magnetic chuck.

In an embodiment, the method may further include, after the aligning the light-emitting elements on the target substrate, drying the ink to fix the light-emitting elements at the aligned positions.

In an embodiment, the method may further include forming a first contact electrode and a second contact electrode on both ends of the light-emitting elements, respectively.

According to an aspect of the disclosure, there is provided a method of fabricating a display device. The method may include preparing a target substrate including alignment electrodes, preparing light-emitting elements formed on a semiconductor substrate, applying ink on the target substrate, supplying the light-emitting elements to the ink by separating the light-emitting elements from the semiconductor substrate above the target substrate, and aligning the light-emitting elements to aligned positions on the target substrate.

In an embodiment, the separating of the light-emitting elements from the semiconductor substrate may include using a cutting unit including a knife or a laser beam to separate the light-emitting elements from the semiconductor substrate.

According to embodiments of the disclosure, ink may be first supplied or applied to a target substrate on which light-emitting elements are to be disposed, then the light-emitting elements may be supplied to the ink, and the light-emitting elements may be aligned on the target substrate. According to embodiments, the light-emitting elements may be appropriately disposed or aligned on the target substrate before the light-emitting elements have settled down in the ink. Accordingly, the light-emitting elements can be aligned more accurately and utilized more efficiently, and the yield of the display device may be increased.

However, effects according to the embodiments of the disclosure are not limited to those described above and various other effects are incorporated herein.

### BRIEF DESCRIPTION OF THE DRAWINGS

The above and other aspects and features of the disclosure will become more apparent by describing in detail embodiments thereof with reference to the attached drawings, whereby sizes, thicknesses, ratios, and dimensions of the elements may be exaggerated for ease of description and for clarify, whereby like reference numbers and/or like reference characters refer to like elements, throughout, and in which:

FIG. 1 is a plan view showing a display device according to an embodiment that is constructed according to principles of the disclosure.

FIG. 2 is a plan view showing a display area of a display device to an embodiment of.

FIG. 3 is a cross-sectional view showing a display device according to an embodiment.

FIG. 4 is a cross-sectional view showing a display device according to an embodiment.

FIG. 5 is a flowchart for illustrating a method of fabricating a display device according to an embodiment.

FIG. 6 is a cross-sectional view showing a target substrate according to an embodiment.

FIG. 7 is a cross-sectional view showing a target substrate according to an embodiment.

FIG. 8 is a perspective view showing a light-emitting element substrate according to an embodiment.

FIGS. 9 to 14 are cross-sectional views showing a method of fabricating a display device according to an embodiment.

FIG. 15 is a cross-sectional view showing a method of fabricating a display device according to an embodiment.

FIG. 16 is a cross-sectional view showing a method of fabricating a display device according to an embodiment.

FIG. 17 is a plan view showing a mask according to an embodiment

FIG. 18 is a cross-sectional view schematically showing area AR1 of FIG. 16.

### DETAILED DESCRIPTION OF THE EMBODIMENTS

Various aspects of the invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

Hereinafter, embodiments will be described in detail with reference to the accompanying drawings.

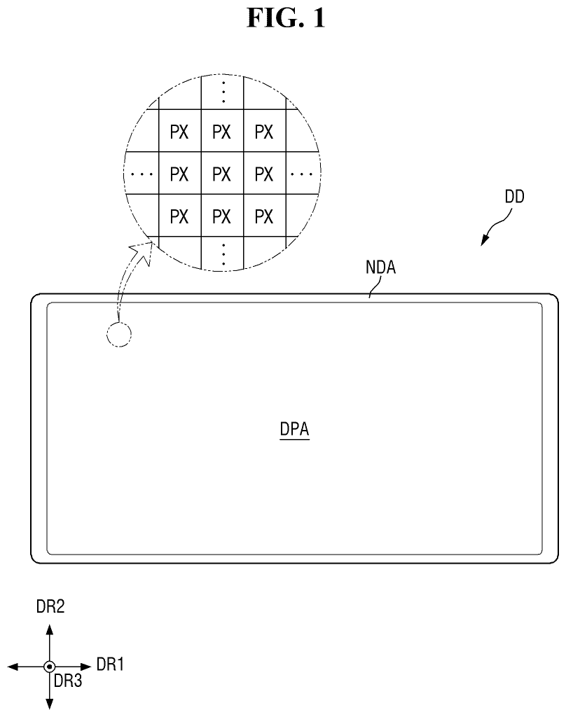

FIG. 1 is a plan view showing a display device DD according to an embodiment that is constructed according to principles of the disclosure.

Referring to FIG. 1, a display device DD for display images may refer to any electronic device that provides a display screen. For example, the display device DD may include a television set, a laptop computer, a monitor, an electronic billboard, the Internet of Things (IoT) devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

The display device DD includes a display panel for providing a display screen. According to an embodiment, the display device DD may be a light-emitting display device and may include a display panel including light-emitting elements. FIG. 1 shows a schematic shape of the display device DD with such a display panel.

In FIG. 1, a first direction DR1, a second direction DR2, and a third direction DR3 are indicated. The first direction DR1 may be the horizontal direction or row direction of the display device DD. The second direction DR2 may intersect the first direction DR1 and, for example, may be the vertical direction or column direction of the display device DD. The third direction DR3 may intersect the first direction DR1 and the second direction DR2 and may be the thickness direction or height direction of the display device DD, for example.

The display device DD may have a variety of shapes. For example, the display device DD may have shapes such as a rectangle with longer lateral sides, a rectangle with longer vertical sides, a square, a quadrangle with rounded corners, other non-rectangular polygons, a circle, an oval, and any other shape.

The display device DD may include a display area DPA where images are displayed. According to an embodiment, the shape of the display area DPA may be similar to the overall shape of the display device DD. According to the embodiment of FIG. 1, the display device DD and the display area DPA have a rectangular shape with longer lateral sides and rounded corners.

The display device DD may include the display area DPA and a non-display area NDA. In the display area DPA, images may be displayed. The non-display area NDA may refer to an area other than the display area DPA, in which images may not be displayed.

The display area DPA may include pixels PX. The pixels PX may be arranged in the display area DPA in a matrix or other pattern. Each of the pixels PX may have a rectangular shape, a square shape, a diamond shape, or other shapes when viewed from the top.

Each of the pixels PX may include at least one light-emitting element that emits light of a particular color. For example, each of the pixels PX may include at least one light-emitting element that emits light of red, green, blue, white, or other colors.

The non-display area NDA may be disposed around the display area DPA. The non-display area NDA may surround the display area DPA entirely or partially. Lines or circuit drivers included in the display device DD may be disposed or external devices may be mounted in the non-display area NDA.

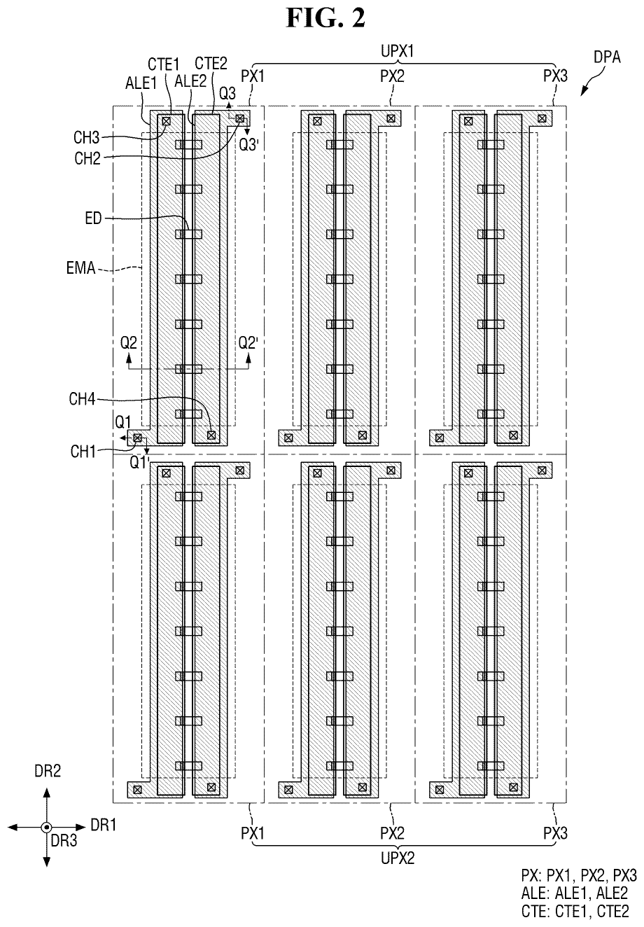

FIG. 2 is a plan view showing the display area DPA of the display device DD according to an embodiment. For example, FIG. 2 shows a part of the display area DPA where some pixels PX of FIG. 1 are arranged. FIG. 2 shows a schematic structure of the pixels PX, focusing on the light-emitting elements ED provided in each of the pixels PX and the electrodes connected to the light-emitting elements ED.

Referring to FIGS. 1 and 2, the display device DD may include a number of pixels PX arranged in the display area DPA. For example, the display device DD may include first pixels PX1 emitting light of a first color (e.g., first color sub-pixels), second pixels PX2 emitting light of a second color (e.g., second color sub-pixels), and third pixels PX3 emitting light of a third color (e.g., third color sub-pixels). According to an embodiment, the first color may be red, the second color may be green, and the third color may be blue. It is, however, to be understood that the embodiment is not limited thereto. At least one first pixel PX1, at least one second pixel PX2 and at least one third pixel PX3 adjacent to one another may form each unit pixel capable of emitting light of various colors. For example, a first pixel PX1, a second pixel PX2 and a third pixel PX3 arranged sequentially in the first direction DR1 in the K^{th} row of the display area DPA may form a first unit pixel UPX1, and a first pixel PX1, a second pixel PX2 and a third pixel PX3 arranged sequentially in the first direction DR1in the (K+1)^{th} row of the display area DPA may form a second unit pixel UPX2, where K is a natural number. The number, type and/or arrangement structure of the pixels PX form each unit pixel may vary depending on the embodiments.

Each of the pixels PX may include at least one pair of alignment electrodes ALE disposed in at least the emission area EMA, and at least one light-emitting element ED disposed between the alignment electrodes ALE. According to an embodiment, each of the pixels PX may further include at least one pair of contact electrodes CTE disposed separately from each other on the both ends of the at least one light-emitting element ED. The emission area EMA may include an area where at least one light-emitting element ED is disposed among pixel areas where the pixels PX are disposed, and may include an area where light emitted from the light-emitting element ED exits. According to an embodiment, the light-emitting elements ED may be ultra-small light-emitting elements with a small size in micrometers or nanometers, and a plurality of light-emitting elements ED may be disposed in the emission area EMA of each of the pixels PX. For example, each of the pixels PX may include a first alignment electrode ALE1 and a second alignment electrode ALE2 disposed in the emission area EMA, light-emitting elements ED disposed between the first alignment electrode ALE1 and the second alignment electrode ALE2, and a first contact electrode CTE1 and a second contact electrode CTE2 disposed on the first and second ends of the light-emitting elements ED.

The first alignment electrode ALE1 and the second alignment electrode ALE2 may be spaced apart from each other. For example, the first alignment electrode ALE1 and the second alignment electrode ALE2 may be spaced apart from each other by a distance less than or equal to the length of the light-emitting elements ED in the first direction DR1 in the emission area EMA. Each of them may have a shape extended in the second direction DR2. The shape, size, number and/or arrangement structure of the alignment electrodes ALE disposed in each emission area EMA may vary depending on the embodiments.

The first alignment electrode ALE1 and the second alignment electrode ALE2 may be connected to voltage lines from which supply voltages of different levels are applied. According to an embodiment, the first alignment electrode ALE1 may be connected to a first voltage line from which a first supply voltage (e.g., a high-level pixel supply voltage) is applied through a first contact hole CH1 and/or at least one circuit element. The second alignment electrode ALE2 may be connected to a second voltage line from which a second supply voltage (e.g., a low-level pixel supply voltage) is applied through a second contact hole CH2. During the process of fabricating the display device DD, alignment signals may be applied to the first alignment electrode ALE1 and the second alignment electrode ALE2. Accordingly, an electric field is formed around the first alignment electrode ALE1 and the second alignment electrode ALE2 so that the light-emitting elements ED can be aligned with an orientation.

The light-emitting elements ED may be arranged in the emission area EMA of each of the pixels PX. According to an embodiment, the light-emitting elements ED may be arranged and/or aligned between the alignment electrodes ALE. For example, in each emission area EMA, the light-emitting elements ED may be arranged substantially in the second direction DR2, and the light-emitting elements ED may be arranged substantially in the first direction DR1. For example, each of the light-emitting elements ED may include a first end (e.g., a p-type end) that overlaps the first alignment electrode ALE1 and is electrically connected to the first alignment electrode ALE1, and a second end (e.g., an n-type end) that overlaps the second alignment electrode ALE2 and is electrically connected to the second alignment electrode ALE2. According to an embodiment, at least one inactive light-emitting element (e.g., a dummy light-emitting element) may be disposed in the emission area EMA of each of the pixels PX and/or in the non-emission area around the emission area EMA, which is not properly aligned or connected between the first alignment electrode ALE1 and the second alignment electrode ALE2 and does not emit light. FIG. 2 shows only the light-emitting elements ED that contribute to the light emission of the pixels PX. Although the same number of light-emitting elements ED are disposed in different pixels PX in FIG. 2, the embodiments described herein are not limited thereto. For example, the pixels PX may include a similar number of light-emitting elements ED. In addition, although each of the light-emitting elements ED is aligned exactly in the first direction DR1 in FIG. 2, some of the light-emitting elements ED may be aligned in a diagonal direction inclined with respect to the first direction DR1 and the second direction DR2, and the first and second ends may be connected to the first alignment electrode ALE1 and the second alignment electrode ALE2, respectively. In addition, although the light-emitting elements ED are arranged at uniform intervals in FIG. 2, the light-emitting elements ED may be arranged at non-uniform intervals.

According to an embodiment, the first pixels PX1, the second pixels PX2 and/or the third pixels PX3 may include light-emitting elements ED that emit lights of different colors. For example, the first pixels PX1, the second pixels PX2 and the third pixels PX3 may include light-emitting elements ED that emit first color light, second color light and third color light, respectively. For example, the first pixels PX1, the second pixels PX2 and the third pixels PX3 may include light-emitting elements ED that emit lights of the same color (e.g., blue light or white light). In the emission areas EMA of the first pixels PX1, the second pixels PX2 and/or the third pixels PX3, light conversion patterns (e.g., wavelength conversion patterns containing quantum dots) and/or color filters for converting and/or controlling the colors of lights emitted from the light-emitting elements ED provided in each of the pixels PX may be disposed.

The first contact electrode CTE1 may be disposed on the first ends of the light-emitting elements ED and connected to the first ends. According to an embodiment, the first contact electrode CTE1 may be electrically connected to the first alignment electrode ALE1 through the third contact hole CH3 penetrating the insulating layer between the first contact electrode CTE1 and the first alignment electrode ALE1, or may be electrically connected to the first alignment electrode ALE1 through a wider opening in the insulating layer in the emission area EMA. According to an embodiment, the first contact electrode CTE1 may be electrically connected to at least one circuit element and/or the first voltage line through the first alignment electrode ALE1. According to another embodiment, the first contact electrode CTE1 may be electrically connected directly to at least one circuit element and/or the first voltage line without passing through the first alignment electrode ALE1.

The second contact electrode CTE2 may be disposed on the second ends of the light-emitting elements ED and electrically connected to the second ends. According to an embodiment, the second contact electrode CTE2 may be electrically connected to the second alignment electrode ALE2 through the fourth contact hole CH4 penetrating the insulating layer between the second contact electrode CTE2 and the second alignment electrode ALE2, or may be electrically connected to the second alignment electrode ALE2 through a wider opening in the insulating layer in the emission area EMA. According to an embodiment, the second contact electrode CTE2 may be electrically connected to the second voltage line through the second alignment electrode ALE2. According to another embodiment, the second contact electrode CTE2 may be electrically connected directly to the second voltage line through the second alignment electrode ALE2.

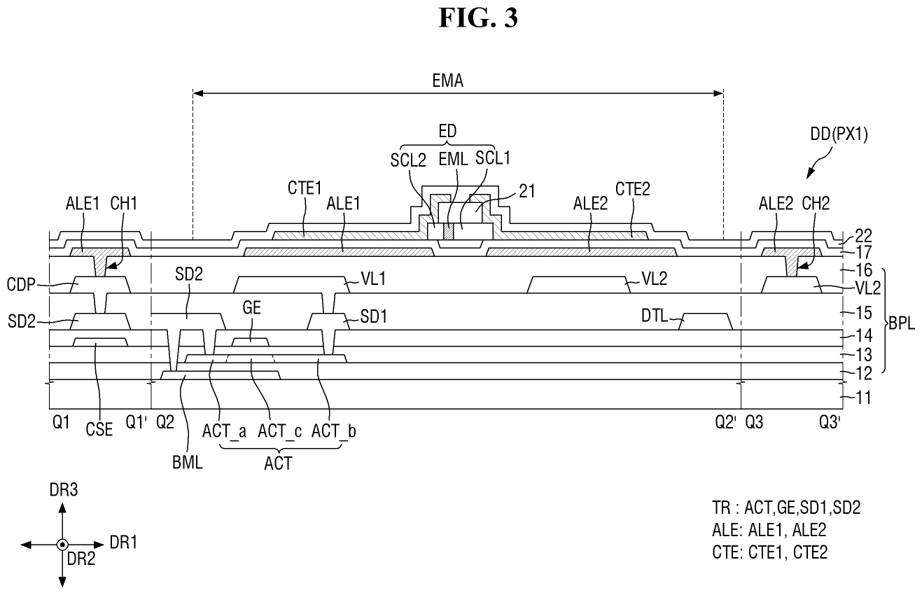

FIG. 3 is a cross-sectional view showing the display device DD according to an embodiment. For example, FIG. 3 shows a cross section of the first pixel PX1, taken along lines Q1-Q1′, Q2-Q2′ and Q3-Q3′ of FIG. 2. Although FIG. 3 shows only the cross section of one first pixel PX1, the other pixels PX, for example, another first pixel PX1, a second pixel PX2 and a third pixel PX3 may have a cross-sectional structure that is substantially the same as or similar to that of the first pixel PX1 of FIGS. 2 and 3. Additionally, the cross section of each of the pixels PX is not limited to the embodiment shown in FIG. 3 and may be altered in various ways. In addition, in some implementations, some pixels PX may have a cross-sectional structure different from that of the other pixels PX.

Referring to FIGS. 1 to 3, the display device DD may include a base substrate 11, alignment electrodes ALE, light-emitting elements ED and contact electrodes CTE disposed on the base substrate 11. The display device DD may further include insulating layers disposed between the alignment electrodes ALE, the light-emitting elements ED, and the contact electrodes CTE.

According to an embodiment, the display device DD may further include a panel circuit layer BPL (or backplane circuit layer) disposed between the base substrate 11 and the alignment electrodes ALE. In the panel circuit layer BPL, circuit elements, lines and/or pads provided to the display panel may be disposed. The panel circuit layer BPL may include at least one semiconductor layer, a plurality of conductive layers, and a plurality of insulating layers. The location of the panel circuit layer BPL may vary depending on the embodiments. According to another embodiment, the display device DD may not include the panel circuit layer BPL. For example, the alignment electrodes ALE may be disposed directly on the base substrate 11, or on a barrier layer or a buffer layer disposed on the base substrate 11.

The base substrate 11 may be a base member for forming the display panel of the display device DD, and may form a base surface of the display panel. The base substrate 11 may be made of an insulating material such as glass, quartz and a polymer resin. The base substrate 11 may be a rigid substrate or a flexible substrate that can be bent, folded, rolled, and so on.

A light-blocking layer BML may be disposed on the base substrate 11. The light-blocking layer BML is disposed to overlap with the active layer ACT of at least one transistor TR provided to each of the pixels PX of the display device DD. According to an embodiment, each of the pixels PX may include a pixel circuit including a plurality of transistors TR and at least one capacitor. FIG. 3 shows only one transistor TR as an example of the circuit elements that may be provided to the pixel circuit.

The light-blocking layer BML may include a material that blocks light, and thus can prevent light from entering the active material layer ACT of the transistor TR. For example, the light-blocking layer BML may be formed of an opaque metal material that blocks light transmission. In some implementations, the display device DD may not include the light-blocking layer BML.

A buffer layer 12 may be disposed on the light-blocking layer BML. For example, the buffer layer 12 may be disposed on the base substrate 11 and may cover the light-blocking layer BML. The buffer layer 12 may include at least one inorganic insulating layer and may protect the pixels PX from permeation of moisture through the base substrate 11 or the like. For example, the buffer layer 12 may include silicon oxide (SiOₓ), silicon nitride (SiNₓ), and silicon oxynitride (SiOₓN_{y}) or other inorganic insulating materials.

A semiconductor layer may be disposed on the buffer layer 12. The semiconductor layer may include the active layer ACT of the transistor TR. The active layer ACT may include polycrystalline silicon, monocrystalline silicon, oxide semiconductor, or other semiconductor materials. The active layer ACT may include a channel region ACT_c overlapping with a gate electrode GE of the transistor TR, and conductive regions ACT_a and ACT_b located on the both sides of the channel region ACT_c (e.g., source and drain regions), respectively.

A first insulating layer 13 may be disposed on the semiconductor layer. For example, the first insulating layer 13 may be disposed on the buffer layer 12 and may cover patterns provided to the semiconductor layer (e.g., the active layer ACT). According to an embodiment, the first insulating layer 13 may include an inorganic insulating material (e.g., silicon oxide (SiOₓ), silicon nitride (SiNₓ), silicon oxynitride (SiOₓN_{y}), or other inorganic insulating material).

A first conductive layer may be disposed on the first insulating layer 13. The first conductive layer may include the gate electrode GE of the transistor TR and a first capacitor electrode CSE. The gate electrode GE may overlap with the channel region ACT_c of the active layer ACT. The first capacitor electrode CSE may be disposed to overlap with the first source/drain electrode SD1 of the transistor TR in the thickness direction. In some implementations, the first capacitor electrode CSE may be connected to the gate electrode GE. For example, the first capacitor electrode CSE and the gate electrode GE may be integrated as a single pattern. As the first capacitor electrode CSE overlaps with the first source/drain electrode SD1, a capacitor (e.g., a storage capacitor of each of the pixels PX) may be formed between the first capacitor electrode CSE and the first source/drain electrode SD1.

The first conductive layer may be made of at least one conductive material (e.g., one of molybdenum (Mo), aluminum (Al), chromium (Cr), gold (Au), titanium (Ti), nickel (Ni), neodymium (Nd) and copper (Cu), an alloy thereof or other conduct materials). The first conductive layer may be made up of a single layer or multiple layers.

A second insulating layer 14 may be disposed on the first conductive layer. For example, the second insulating layer 14 may be disposed on the first insulating layer 13, and may cover the patterns of the first conductive layer (e.g., the gate electrode GE of the transistor TR and the first capacitor electrode CSE). According to an embodiment, the second insulating layer 14 may include an inorganic insulating material (e.g., silicon oxide (SiOₓ), silicon nitride (SiNₓ), silicon oxynitride (SiOₓN_{y}), or other inorganic insulating material).

A second conductive layer may be disposed on the second insulating layer 14. The second conductive layer may include a first source/drain electrode SD1 and a second source/drain electrode SD2 of the transistor TR and a data line DTL. The first source/drain electrode SD1 may be one of the source electrode and drain electrode of the transistor TR, and the second source/drain electrode SD2 may be the other one of the source electrode and drain electrode of the transistor TR.

The first source/drain electrode SD1 and the second source/drain electrode SD2 of the transistor TR may be electrically connected to the conductive regions ACT_a and ACT_b of the active layer ACT. For example, the first source/drain electrode SD1 of the transistor TR may be electrically connected to the conductive region ACT_a (e.g., a source region) located on one side of the active layer ACT through a contact hole penetrating the second insulating layer 14 and the first insulating layer 13. The second source/drain electrode SD2 of the transistor TR may be electrically connected to the conductive region ACT_b (e.g., a drain area) located on the other side of the active layer ACT through another contact hole penetrating the second insulating layer 14 and the first insulating layer 13. According to an embodiment, the second source/drain electrode SD2 of the transistor TR may be electrically connected to the light-blocking layer BML through a contact hole penetrating through the second insulating layer 14, the first insulating layer 13 and the buffer layer 12.

The data line DTL may apply a data signal to another transistor provided in the pixel PX. In some implementations, the data line DTL may be connected to a source/drain electrode of another transistor.

The second conductive layer may be made of at least one conductive material (e.g., one of molybdenum (Mo), aluminum (Al), chromium (Cr), gold (Au), titanium (Ti), nickel (Ni), neodymium (Nd) and copper (Cu), an alloy thereof or other conduct materials). The second conductive layer may be made up of a single layer or multiple layers.

A third insulating layer 15 may be disposed on the second conductive layer. For example, the third insulating layer 15 may be disposed on the second insulating layer 14 and cover the second conductive layer. According to an embodiment, the third insulating layer 15 may include an inorganic insulating material (e.g., silicon oxide (SiOₓ), silicon nitride (SiNₓ), silicon oxynitride (SiOₓN_{y}), or other inorganic insulating material).

A third conductive layer may be disposed on the third insulating layer 15. The third conductive layer may include a first voltage line VL1, a second voltage line VL2, and a first conductive pattern CDP. According to an embodiment, the first voltage line VL1 may be a power line from which a first supply voltage at a high level is applied, and the second voltage line VL2 may be a power line from which a second supply voltage at a low level is applied. According to an embodiment, the first voltage line VL1 may be connected to the first ends of the light-emitting elements ED via at least one transistor TR, the first alignment electrode ALE1 and the first contact electrode CTE1 provided in each of the pixels PX. The second voltage line VL2 may be connected to the second ends of the light-emitting elements ED via the second alignment electrode ALE2 and the second contact electrode CTE2 provided in each of the pixels PX.

The first conductive pattern CDP may be electrically connected to the first source/drain electrode SD1 of the transistor TR through a contact hole formed in the third insulating layer 15. The first conductive pattern CDP may also be electrically connected to the first alignment electrode ALE1. The transistor TR may transfer the first supply voltage applied from the first voltage line VL1 to the first alignment electrode ALE1 through the first conductive pattern CDP. According to an embodiment, at least a part of the first alignment electrode ALE1 may overlap with the first voltage line VL1. Although the third conductive layer includes one second voltage line VL2 and one first voltage line VL1 in the example shown in FIG. 3, the embodiment is not limited thereto. For example, the third conductive layer may include more than one first voltage lines VL1 and second voltage lines VL2.

The third conductive layer may be made of at least one conductive material (e.g., one of molybdenum (Mo), aluminum (Al), chromium (Cr), gold (Au), titanium (Ti), nickel (Ni), neodymium (Nd) and copper (Cu), an alloy thereof or other conduct materials). The third conductive layer may be made up of a single layer or multiple layers.

A fourth insulating layer 16 (e.g., a planarization layer) may be disposed on the third conductive layer. The fourth insulating layer 16 may include an organic insulating material (e.g., polyimide (PI) or other organic insulating materials). The surface of the fourth insulating layer 16 may be substantially flat.

The above-described first conductive layer to fourth insulating layer 16 (or the light-blocking layer BML to the fourth insulating layer 16) may form the panel circuit layer BPL in which circuit elements provided in the display panel (e.g., transistors and capacitors forming the pixel circuits of the pixels PX and/or the panel-embedded driver circuits) and lines are provided. According to thane embodiment, the base substrate 11 and the panel circuit layer BPL may form a lower substrate of the display device DD (e.g., a backplane substrate of the display panel).

A light-emitting element layer including light-emitting elements ED may be disposed on the panel circuit layer BPL. As an example, the light-emitting element layer may be disposed on the fourth insulating layer 16. According to an embodiment, the light-emitting element layer may include alignment electrodes ALE to which alignment signals are applied during the process of fabricating the display device DD, light-emitting elements ED disposed and/or aligned between the alignment electrodes ALE, and contact electrodes CTE that are in contact with and/or connected to the both ends of the light-emitting elements ED. The light-emitting element layer may further include a fifth insulating layer 17, a sixth insulating layer 21 and a seventh insulating layer 22 disposed between or around the alignment electrodes ALE, the light-emitting elements ED, and the contact electrodes CTE.

Specifically, the alignment electrodes ALE may be disposed on the panel circuit layer BPL. For example, the alignment electrodes ALE may be disposed on the fourth insulating layer 16. Each of the alignment electrodes ALE may be a single-layer or multi-layer electrode containing at least one conductive material. According to an embodiment, each of the alignment electrodes ALE may be a reflective electrode including a highly reflective conductive material (e.g., silver (Ag), copper (Cu), aluminum (Al), or other reflective metals). Accordingly, the emission efficiency of the pixels PX can be increased.

According to an embodiment, the first alignment electrode ALE1 may be electrically connected to at least one transistor TR provided in each of the pixels PX through a first contact hole CH1. For example, the first alignment electrode ALE1 may be in contact with the first conductive pattern CDP through the first contact hole CH1 penetrating the fourth insulating layer 16, and may be electrically connected to at least one transistor TR provided in that pixel PX through the first conductive pattern CDP.

According to thane embodiment, the second alignment electrode ALE2 may be electrically connected to the second voltage line VL2 through the second contact hole CH2. For example, the second alignment electrode ALE2 may be in contact with the second voltage line VL2 through the second contact hole CH2 penetrating the fourth insulating layer 16.

The fifth insulating layer 17 (also referred to as “first capping layer”) may be disposed on the alignment electrodes ALE. For example, the fifth insulating layer 17 may be disposed on the fourth insulating layer 16 and cover the alignment electrodes ALE.

The light-emitting elements ED may be disposed on the fifth insulating layer 17. Each of the light-emitting elements ED may include a first semiconductor layer SCL1, a second semiconductor layer SCL2, and an emissive layer EML (also referred to as “the active layer” of the light-emitting element ED) interposed between the first and second semiconductor layers SCL1 and SCL2. For example, a light-emitting element ED may include a first semiconductor layer SCL1, an emission layer EML and a second semiconductor layer SCL2 arranged sequentially from one end (e.g., a second end) to the other end (e.g., a first end) in the longitudinal direction. According to an embodiment, the light-emitting element ED may further include an insulating film surrounding at least the outer peripheral surface of the emissive layer EML. According to an embodiment, the light-emitting element ED may further include at least one electrode layer located at at least one end.

According to an embodiment, the light-emitting element ED may have size in micrometers or nanometers and may be a light-emitting diode made of an inorganic material. According to an embodiment, the light-emitting element ED may have a rod shape extended in a direction. The first semiconductor layer SCL1 and the second semiconductor layer SCL2 may be located at different ends, respectively, in the longitudinal direction of the light-emitting element ED. As an example, the light-emitting element ED may be a rod-shaped inorganic light-emitting diode with a length ranging from several micrometers to tens of micrometers (e.g., a length having a value in the range of approximately 1 μm to 10 μm or 2 μm to 6 μm), and a diameter having a value ranging from tens of nanometers to hundreds of nanometers (e.g., a diameter having a value in the range of 30 nm to 700 nm). It should be understood, however, that the embodiments are not limited thereto. The type, shape and size of the light-emitting element ED may vary depending on the embodiments.

The first semiconductor layer SCL1 may include a semiconductor of a first conductivity type including a dopant of the first conductivity type. For example, the first semiconductor layer SCL1 may be an n-type semiconductor layer containing an n-type dopant.

According to an embodiment, the first semiconductor layer SCL1 may include a nitride semiconductor material or a phosphide semiconductor material. For example, the first semiconductor layer SCL1 may include a nitride semiconductor material including at least one of GaN, AlGaN, InGaN, AlInGaN, AlN and InN, or a phosphide semiconductor material including at least one of GaP, GalnP, AlGaP, AlGaInP, AlP and InP. The first semiconductor layer SCL1 may include other materials. According to an embodiment, the first semiconductor layer SCL1 may include an n-type dopant such as Si, Ge and Sn. The first semiconductor layer SCL1 may include other dopants.

The emissive layer EML may be disposed on the first semiconductor layer SCL1. The emissive layer EML may include a single or multiple quantum well structure. The light-emitting element ED may emit light with a luminance in proportional to the driving current transmitted from the pixel circuit.

According to an embodiment, the emissive layer EML may emit light in a visible wavelength range, for example, light in a wavelength range of approximately 400 nm to 900 nm. For example, the emissive layer EML may emit blue light with a peak wavelength ranging from approximately 440 nm to 480 nm, green light with a peak wavelength ranging from approximately 510 nm to 550 nm, or red light with a peak wavelength ranging from approximately 610 nm to 650 nm. The emissive layer EML may emit light in other colors and/or wavelength ranges in addition to the colors and/or wavelength ranges mentioned above.

According to an embodiment, the emissive layer EML may include a nitride semiconductor material or a phosphide semiconductor material. For example, the emissive layer EML may include a nitride semiconductor material including at least one of GaN, AlGaN, InGaN, InGaAlN, AlN and InN, or a phosphide semiconductor material including at least one of GaP, GalnP, AlGaP, AlGaInP, AlP and InP. The emissive layer EML may include other materials.

The second semiconductor layer SCL2 may be disposed on the emissive layer EML. The second semiconductor layer SCL2 may include a semiconductor layer of a second conductivity type that includes a dopant of the second conductivity type. For example, the second semiconductor layer SCL2 may be a p-type semiconductor layer including a p-type dopant.

According to an embodiment, the second semiconductor layer SCL2 may include a nitride semiconductor material or a phosphide semiconductor material. For example, the second semiconductor layer SCL2 may include a nitride semiconductor material including at least one of GaN, AlGaN, InGaN, AlInGaN, AlN and InN, or a phosphide semiconductor material including at least one of GaP, GalnP, AlGaP, AlGalnP, AlP and InP. The second semiconductor layer SCL2 may include other materials. According to an embodiment, the second semiconductor layer SCL2 may include a p-type dopant such as Mg. The second semiconductor layer SCL2 may include other dopants.

According to an embodiment, the first semiconductor layer SCL1 and the second semiconductor layer SCL2 may have different lengths (or thicknesses) in the longitudinal direction of the light-emitting element ED. For example, the first semiconductor layer SCL1 may have a larger than length (or a greater thickness) than the second semiconductor layer SCL2 along the longitudinal direction of the light-emitting element ED.

According to an embodiment, the sixth insulating layer 21 (or insulating pattern) may be disposed on a part of the light-emitting elements ED. For example, the sixth insulating layer 21 may be disposed on a portion including the central portion of each of the light-emitting elements ED but not on the other portions including the both ends of each of the light-emitting elements ED (e.g., the both ends in the longitudinal direction). Accordingly, the both ends of each of the light-emitting elements ED may be exposed without being covered by the sixth insulating layer 21. The sixth insulating layer 21 may protect the light-emitting elements ED and fix the light-emitting elements ED at the aligned positions during the process of fabricating the display device DD. In some implementations, the display device DD may not include the sixth insulating layer 21.

Contact electrodes CTE may be disposed on the both ends of each of the light-emitting elements ED. For example, a first contact electrode CTE1 may be disposed on a first end (e.g., p-type end) of each of the light-emitting elements ED, and a second contact electrode CTE2 may be disposed on a second end (e.g., n-type end) of each of the light-emitting elements ED. The first contact electrode CTE1 and the second contact electrode CTE2 may be electrically connected to the light-emitting elements ED disposed in the respective emission areas EMA. While the display device DD is driven, electrical signals may be applied to the light-emitting elements ED through the first and second contact electrodes CTE1 and CTE2. Each of the contact electrodes CTE may be a single-layer or multi-layer electrode containing at least one conductive material. According to an embodiment, each of the contact electrodes CTE may be a transparent electrode containing a transparent conductive material (e.g., indium tin oxide (ITO), indium zinc oxide (IZO), indium tin-zinc oxide (ITZO), or other transparent conductive materials). Accordingly, light emitted from the light-emitting elements ED may pass through the contact electrodes CTE.

According to an embodiment, the first contact electrode CTE1 may be electrically connected to the first alignment electrode ALE1 through an opening or a contact hole (e.g., the third contact hole CH3 in FIG. 2) formed in the fifth insulating layer 17 on the first alignment electrode ALE1. The first contact electrode CTE1 may be electrically connected to at least one of the conductive pattern CDP, the transistor TR and the first voltage line VL1 of the panel circuit layer BPL through the first alignment electrode ALE1.

According to an embodiment, the second contact electrode CTE2 may be electrically connected to the second alignment electrode ALE2 through an opening or a contact hole (e.g., the fourth contact hole CH4 in FIG. 2) formed in the fifth insulating layer 17 on the second alignment electrode ALE2. The second contact electrode CTE2 may be electrically connected to the second voltage line VL2 of the panel circuit layer BPL through the second alignment electrode ALE2.

The seventh insulating layer 22 may be disposed on the contact electrodes CTE. For example, the seventh insulating layer 22 may be disposed on the fifth insulating layer 17 and the sixth insulating layer 21 and may cover the contact electrodes CTE. According to an embodiment, the seventh insulating layer 22 may be a common layer disposed entirely in the display area DPA.

Each of the fifth insulating layer 17, the sixth insulating layer 21 and the seventh insulating layer 22 may be a single-layer or multi-layer insulating layer including an inorganic insulating material and/or an organic insulating material. For example, each of the fifth insulating layer 17, the sixth insulating layer 21 and the seventh insulating layer 22 may include at least one of: silicon oxide (SiOₓ), silicon nitride (SiNₓ), silicon oxynitride (SiOₓN_{y}), aluminum oxide (Al₂O₃), aluminum nitride (AlN), or other inorganic insulating materials, and an acrylic resin, an epoxy resin, a phenol resin, a polyamide resin, a polyimide resin, an unsaturated polyester resin, a polyphenylene resin, a polyphenylene sulfide resin, benzocyclobutene, a cardo resin, a siloxane resin, a silsesquioxane resin, a polymethyl methacrylate, polycarbonate, a polymethyl methacrylate-polycarbonate synthetic resin, or other organic insulating materials.

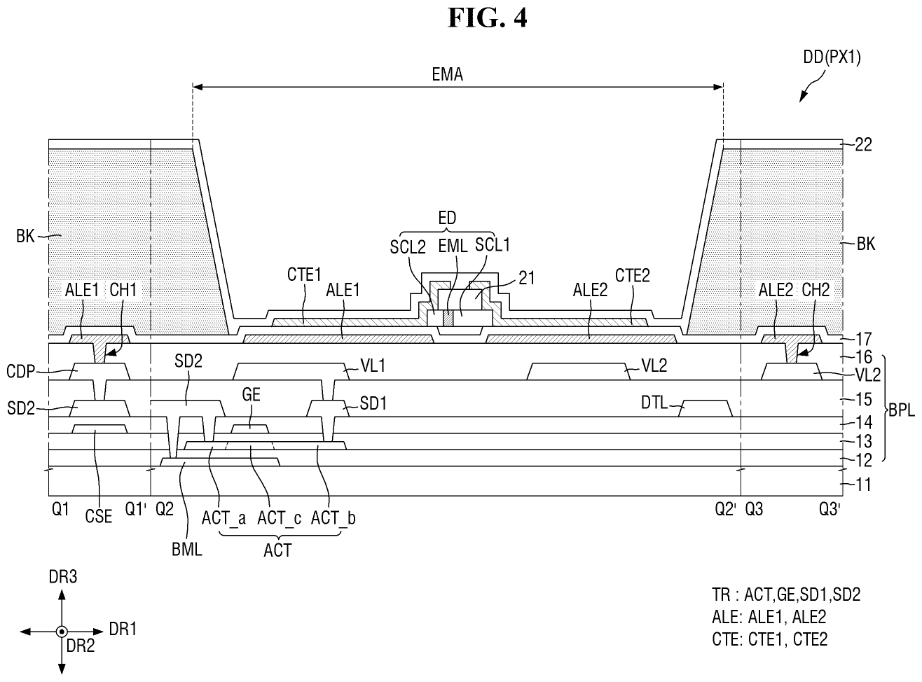

FIG. 4 is a cross-sectional view showing the display device DD according to an embodiment. For example, FIG. 4 shows an embodiment different from the embodiment of FIG. 3 with respect to the cross section of the first pixel PX1 along lines Q1-Q1′, Q2-Q2′, and Q3-Q3′ of FIG. 2.

Referring to FIG. 4 in conjunction with FIGS. 1 to 3, a display device DD may further include a bank BK located around an emission area EMA. For example, the display device DD may include a bank BK surrounding an emission area EMA of each of the pixels PX. According to an embodiment, the bank BK may be an insulating pattern (e.g., a mesh-shaped insulating pattern) that has openings associated with or corresponding to the emission areas EMA of the pixels PX and is in the display area DA to surround the emission areas EMA on all sides. For example, the bank BK may be implemented as a plurality of insulating patterns (e.g., a pair of insulating patterns spaced apart from each other in the first direction DR1), each extended in the second direction DR2 and disposed on the both sides of the emission area EMA.

According to an embodiment, the bank BK may be disposed between the fifth insulating layer 17 and the seventh insulating layer 22. For example, the bank BK may be disposed on the fifth insulating layer 17 and covered with the seventh insulating layer 22. It should be noted that the location of the bank BK is not limited to this and may vary depending on embodiments.

According to an embodiment, the bank BK may include at least one organic insulating layer. According to an embodiment, the bank BK may include inclined surfaces that are inclined at a certain angle or have a gently curved shape. At least some of the lights emitted from the light-emitting elements ED may travel toward the inclined side surface of the bank BK.

According to an embodiment, the display device DD may further include a reflective pattern layer disposed on the bank BK. As an example, the display device DD may include a reflective pattern layer disposed on the side surface and/or upper surface of the bank BK. Reflective partition walls may be formed on the outer side of the emission areas EMA by the bank BK and the reflective pattern layer. Accordingly, the emission efficiency of the pixels PX may be increased.

According to an embodiment, the display device DD may further include an inactive light-emitting element located in a non-light-emitting area. As an example, the display device DD may further include at least one inactive light-emitting element located on the bank BK.

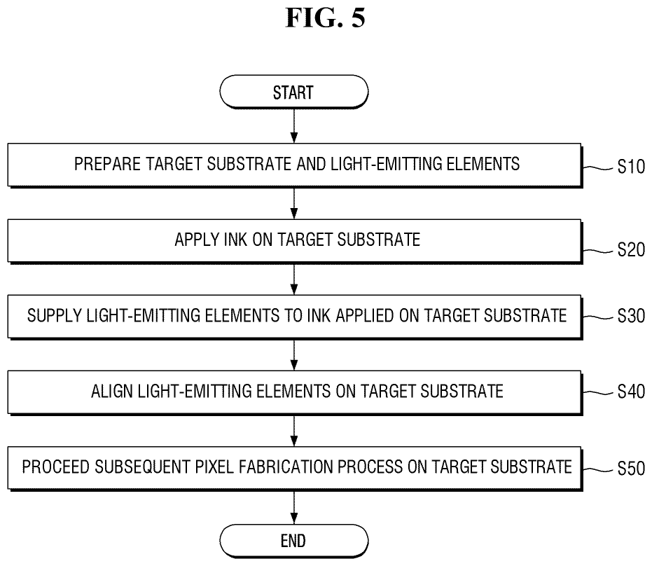

FIG. 5 is a flowchart for illustrating a method of fabricating a display device according to an embodiment.

Referring to FIG. 5 in conjunction with FIGS. 1 to 4, a method of fabricating a display device according to an embodiment may include: preparing a target substrate and light-emitting elements ED (step S10); applying an ink on the target substrate (step S20); supplying light-emitting elements ED to the ink applied on the target substrate (step S30); aligning the light-emitting elements ED on the target substrate (step S40); and proceeding with subsequent processes of fabricating pixels on the target substrate (step S50). For example, the method of fabricating the display device according to the embodiment of FIG. 5 may include disposing the light-emitting elements ED on the target substrate including alignment electrodes ALE, and conducting processes of fabricating the pixels following the disposing the light-emitting elements ED (e.g., a process of forming the sixth insulating layer 21, the contact electrodes CTE and the seventh insulating layer 22).

According to embodiments, the target substrate may be a fabrication substrate for the display device DD in which alignment electrodes ALE and the like are disposed on a lower substrate of the display device DD including the base substrate 11. According to embodiments, the light-emitting elements ED may be prepared on a semiconductor substrate and patterned into a rod shape.

According to embodiments, prior to supplying or disposing light-emitting elements ED on the target substrate, ink that does not contain light-emitting elements ED is first supplied or applied, and then light-emitting elements ED are supplied to the ink applied on the target substrate, such that the light-emitting elements ED may be aligned on the target substrate. According to an embodiment, the ink supplied or applied to the target substrate prior to the light-emitting elements ED may be a high viscosity ink.

The target substrate and the light-emitting elements ED and the method of fabricating the display device DD using them according to embodiments will be described in more detail below.

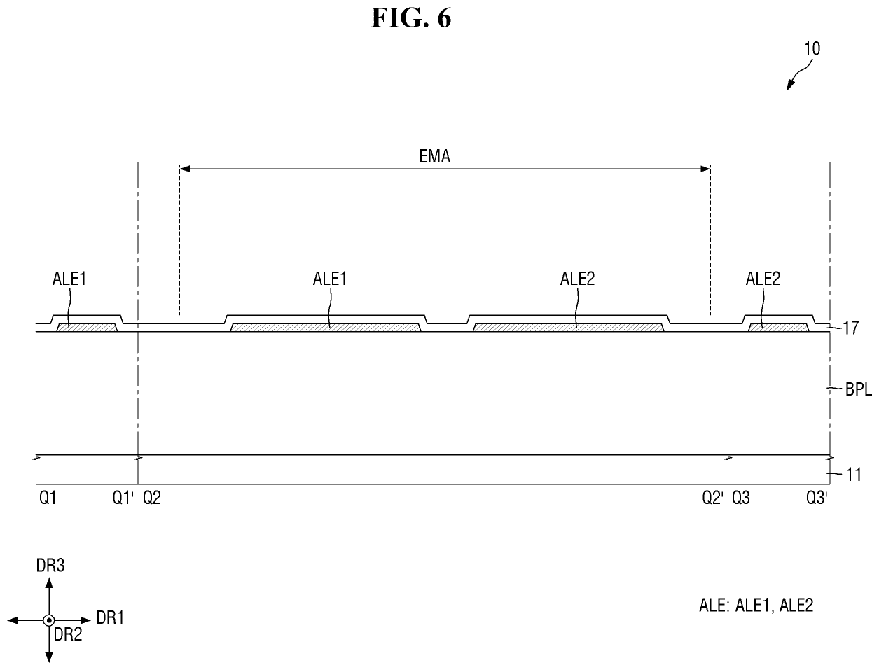

FIG. 6 is a cross-sectional view showing a target substrate 10 according to an embodiment. For example, FIG. 6 schematically shows a cross section of a target substrate 10 for fabricating the display device DD according to the embodiment of FIGS. 2 and 3. FIG. 6 shows a cross-section of a part of the target substrate 10 taken along lines Q1-Q1′, Q2-Q2′ and Q3-Q3′ of FIG. 2.

Referring to FIG. 6 in conjunction with FIGS. 1 to 5, the target substrate 10 may be a substrate on which the light-emitting elements ED are supplied and/or disposed during the process of fabricating the display device DD. For example, the target substrate 10 may be a display panel under fabrication.

According to embodiments, the target substrate 10 may include alignment electrodes ALE disposed in at least respective emission areas EMA on the base substrate 11. According to an embodiment, the target substrate 10 may further include a fifth insulating layer 17 covering the alignment electrodes ALE. According to an embodiment, the target substrate 10 may further include a panel circuit layer BPL disposed between the base substrate 11 and the alignment electrodes ALE.

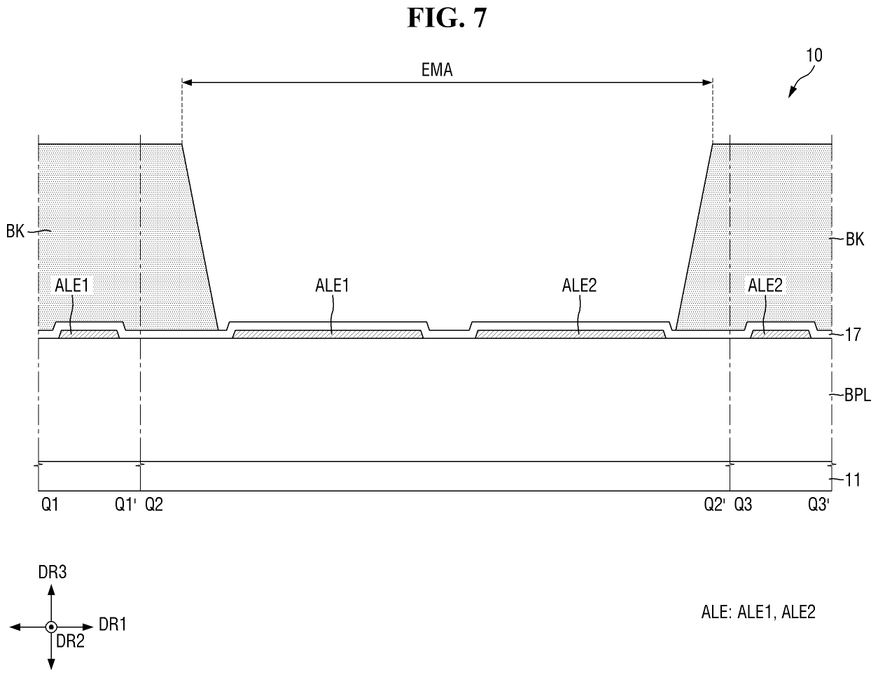

FIG. 7 is a cross-sectional view showing a target substrate 10 according to an embodiment. For example, FIG. 7 schematically shows a cross section of a target substrate 10 for fabricating the display device DD according to the embodiment of FIGS. 2 and 4. FIG. 7 shows a cross-section of a part of the target substrate 10 taken along lines Q1-Q1′, Q2-Q2′ and Q3-Q3′ of FIG. 2.

Referring to FIG. 7 in conjunction with FIGS. 1 to 6, the target substrate 10 includes a base substrate 11 and alignment electrodes ALE, and may further include a bank BK disposed around the emission area EMA. For example, the display panel of the display device DD may be fabricated by disposing the light-emitting elements ED on the target substrate 10 where the emission areas EMA are defined by the bank BK.

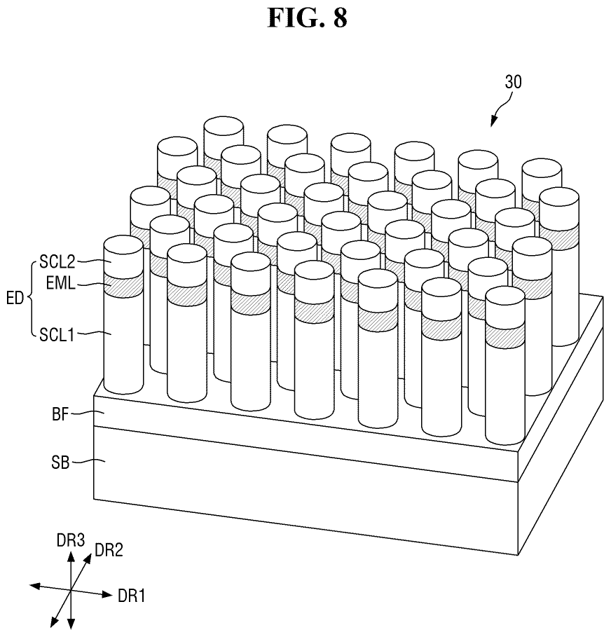

FIG. 8 is a perspective view showing a light-emitting element substrate 30 according to an embodiment. For example, FIG. 8 schematically shows the light-emitting element substrate 30 including light-emitting elements ED provided in the emission area EMA of each of the pixels PX and used as a light source for the respective pixels PX.

Referring to FIG. 8 in addition to FIGS. 1 to 7, the light-emitting element substrate 30 may include a semiconductor substrate SB and light-emitting elements ED formed on the semiconductor substrate SB. Each of the light-emitting elements ED may include a first semiconductor layer SCL1, an emissive layer EML, and a second semiconductor layer SCL2 formed or disposed on the semiconductor substrate SB. According to an embodiment, the light-emitting element substrate 30 may further include a buffer layer BF disposed between the semiconductor substrate SB and the light-emitting elements ED.

According to embodiments, the light-emitting elements ED may be prepared such that they are connected with one another at least through the semiconductor substrate SB. For example, the light-emitting elements ED may be connected with one another through the semiconductor substrate SB and the buffer layer BF.

The light-emitting elements ED may be formed simultaneously on the semiconductor substrate SB. For example, a buffer layer BF may be formed on the semiconductor substrate SB, and a first semiconductor layer SCL1, an emissive layer EML and a second semiconductor layer SCL2 may be sequentially formed on the buffer layer BF. The first semiconductor layer SCL1, the emissive layer EML and the second semiconductor layer SCL2 may be formed by epitaxial growth.

According to embodiments, the light-emitting elements ED may be patterned into a rod shape. For example, by etching the first semiconductor layer SCL1, the emissive layer EML and the second semiconductor layer SCL2 grown on the semiconductor substrate SB in the thickness direction (for example, in the third direction DR3), a plurality of light-emitting elements ED each having a rod shape can be formed. According to an embodiment, the first semiconductor layer SCL1 may be etched to its entire thickness or partially. When the first semiconductor layer SCL1 is etched to the entire thickness, the first semiconductor layers SCL1 of the light-emitting elements ED may be spaced apart or separated from one another, and may be connected through the buffer layer BF (or semiconductor substrate SB). When the first semiconductor layer SCL1 is etched partially, the lower portions of the first semiconductor layers SCL1 may be connected with one another near the buffer layer BF. According to embodiments, each of the light-emitting elements ED may refer to a portion patterned into a rod shape. In supplying the light-emitting elements ED on the target substrate 10, they may be separated from the semiconductor substrate SB, the buffer layer BF, etc. to form individual light-emitting elements ED.

The substrate SB (also referred to as “growth substrate” or “fabrication substrate”) may be a fabrication substrate or wafer suitable for epitaxial growth of a semiconductor. For example, the substrate SB may be a substrate including a material such as silicon (Si), sapphire, SiC, GaN, GaAs and ZnO. Besides, a substrate of various types and/or materials may be used as the substrate SB. The type or material of the substrate SB is not particularly limited as long as epitaxial growth for fabricating the light-emitting element ED can be performed well. The substrate SB may ultimately be separated from the light-emitting elements ED after being used as the substrate for epitaxial growth for fabricating the light-emitting element ED.

According to an embodiment, a buffer layer BF may be disposed on the substrate SUB. The buffer layer BF may be formed by epitaxial growth on the substrate SB, and may ultimately be separated from the light-emitting elements ED. The buffer layer BF may be located between the light-emitting elements ED and the substrate SB during the process of fabricating the light-emitting elements ED, and may physically separate the light-emitting elements ED from the substrate SB. According to an embodiment, the buffer layer BF may be a single-layer or multi-layer semiconductor layer including an intrinsic semiconductor layer that is not doped with impurities, and may include the same semiconductor material as the first semiconductor layer SCL1.

A first semiconductor layer SCL1, an emissive layer EML and a second semiconductor layer SCL2 may be sequentially disposed on the buffer layer BF (or substrate SB). For example, the first semiconductor layer SCL1, the emissive layer EML and the second semiconductor layer SCL2 may be sequentially formed by epitaxial growth on the substrate SB on which the buffer layer BF is formed.

The first semiconductor layer SCL1 may be formed of the above-listed materials for the first semiconductor layer SCL1 or other semiconductor materials. The first semiconductor layer SCL1 may be doped to include an n-type dopant such as Si, Ge and Sn.

The first semiconductor layer SCL1 may be formed by epitaxial growth utilizing process technologies such as metal-organic vapor phase epitaxy (MOVPE), metal-organic chemical vapor deposition (MOCVD), molecular beam epitaxy (MBE), liquid phase epitaxy (LPE), and vapor phase epitaxy (VPE). It should be understood, however, that the method of forming the first semiconductor layer SCL1 is not limited thereto.

The emissive layer EML may be formed of the above-listed materials for the emissive layer EML, or other semiconductor materials. According to an embodiment, the emissive layer EML may be formed by epitaxial growth using a process technology such as MOVPE, MOCVD, MBE, LPE and VPE. It should be understood, however, that the method of forming the emissive layer EML is not limited thereto.

The second semiconductor layer SCL2 may be formed of the above-listed materials for the second semiconductor layer SCL2 or other semiconductor materials. The second semiconductor layer SCL2 may be doped to include a p-type dopant such as Mg. According to an embodiment, the second semiconductor layer SCL2 may be formed by epitaxial growth using a process technology such as MOVPE, MOCVD, MBE, LPE and VPE. It should be understood, however, that the method of forming the second semiconductor layer SCL2 is not limited thereto.

The first semiconductor layer SCL1, the emissive layer EML and the second semiconductor layer SCL2 may be etched in the thickness direction. Accordingly, the light-emitting elements ED may be patterned into a rod shape.

According to an embodiment, the first semiconductor layer SCL1, the emissive layer EML and the second semiconductor layer SCL2 may be etched in a direction substantially perpendicular to the semiconductor substrate SB. Accordingly, each of the light-emitting elements ED may have a uniform diameter (or width). As an example, each of the light-emitting elements ED may have a rectangular cross-sectional shape. According to another embodiment, the first semiconductor layer SCL1, the emissive layer EML and the second semiconductor layer SCL2 may be etched in a diagonal direction inclined with respect to the semiconductor substrate SB. Accordingly, each of the light-emitting elements ED may have a width that gradually increases or decreases toward one end. For example, each of the light-emitting elements ED may have a trapezoidal or inverted trapezoidal cross-sectional shape. Besides, the shape of the light-emitting elements ED may be changed in a variety of ways.

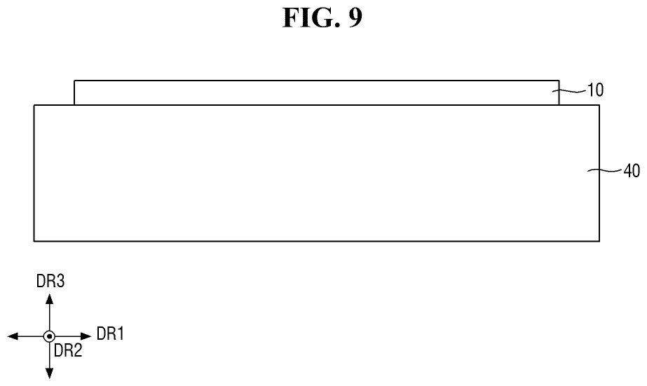

FIGS. 9 to 14 are cross-sectional views illustrating a method of fabricating a display device according to an embodiment. For example, FIGS. 9 to 14 show processing steps of supplying and aligning light-emitting elements ED on the target substrate 10, and subsequent processes of fabricating pixels during the processes of fabricating the display device DD according to the embodiment of FIGS. 2 and 3. The method of fabricating the display device DD according to the embodiment of FIGS. 9 to 14 may also be applied for fabricating display devices having different structures. As an example, the method of fabricating the display device DD according to the embodiment of FIGS. 9 to 14 may also be applied for fabricating a display device that further includes a bank BK, like in the embodiment of FIG. 4.

Referring to FIGS. 9 to 14 in conjunction with FIGS. 1 to 8, a target substrate 10 on which light-emitting elements ED are to be disposed, and light-emitting elements ED to be disposed on the target substrate 10 may be prepared. Once the target substrate 10 and the light-emitting elements ED are prepared, the target substrate 10 may be placed on a stage 40 as shown in FIG. 9. The stage 40 may support the target substrate 10.

According to an embodiment, the target substrate 10 may include a base substrate 11 and alignment electrodes ALE disposed on the base substrate 11 as shown in FIG. 6 or 7. The target substrate 10 may further include a fifth insulating layer 17 covering the alignment electrodes ALE. For example, the preparing the target substrate 10 may include forming alignment electrodes ALE on the base substrate 11, and forming the fifth insulating layer 17 on the alignment electrodes ALE. According to an embodiment, the target substrate 10 may further include a panel circuit layer BPL disposed between the base substrate 11 and the alignment electrodes ALE. For example, the preparing the target substrate 10 may further include forming the panel circuit layer BPL on the base substrate 11 prior to forming the alignment electrodes ALE on the base substrate 11, and the alignment electrodes ALE may be formed on the panel circuit layer BPL. According to an embodiment, the target substrate 10 may further include a bank BK located around the emission area EMA. For example, the preparing the target substrate 10 may further include forming the bank BK on the fifth insulating layer 17.

According to an embodiment, the light-emitting elements ED may be prepared as they are formed and patterned on the semiconductor substrate SB, as shown in FIG. 8, without being separated from the semiconductor substrate SB. For example, the preparing the light-emitting elements ED may include fabricating or preparing a light-emitting element substrate 30 (e.g., an LED wafer) including the semiconductor substrate SB and light-emitting elements ED formed on the semiconductor substrate SB. The light-emitting elements ED may be etched into a rod shape on the semiconductor substrate ED and may be prepared such that they are connected with one another through the semiconductor substrate SB.

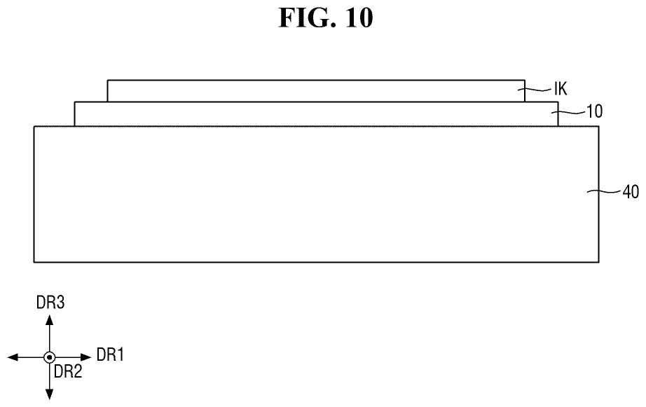

After the target substrate 10 is placed on the stage 40, ink IK may be supplied or applied on the target substrate 10 as shown in FIG. 10. According to an embodiment, the ink IK may be supplied or applied on the target substrate 10 using spraying, slot-die coating, inkjet printing, screen printing, or other techniques. By using inkjet printing or screen printing, the ink IK can be appropriately supplied or applied to a desired location (e.g., emission areas EMA). As a result, the ink IK can be used more efficiently.

According to an embodiment, the surface of the target substrate 10 may be partially or entirely hydrophobic or liquid-repellent. For example, the target substrate 10 may be made of a hydrophobic or liquid-repellent material, or may be surface-treated to have hydrophobic or liquid-repellent properties. For example, a pattern having hydrophobic or liquid-repellent properties may be provided on the target substrate 10. By appropriately adjusting the amount of the ink IK applied on the target substrate 10, it is possible to prevent the ink IK from flowing down on the target substrate 10. It should be understood, however, that the embodiments described herein are not limited thereto. For example, the area where the ink IK is applied may be controlled using a dam-shaped structure.

According to an embodiment, the target substrate 10 may include a bank BK that defines emission areas EMA where the ink IK and the light-emitting elements ED are to be supplied. According to an embodiment, the bank BK may be surface-treated to have hydrophobic or liquid-repellent properties, or may include a pattern that has hydrophobic or liquid-repellent properties. Accordingly, the ink IK and the light-emitting elements ED can be appropriately supplied to the emission areas EMA.

According to embodiments, the ink IK may be prepared without containing light-emitting elements ED and applied on the target substrate 10 prior to the light-emitting elements ED. After the ink IK is applied on the target substrate 10, the light-emitting elements ED are supplied to the applied ink IK, thereby giving fluidity to the light-emitting elements ED and slowing down settlement of the light-emitting elements ED. According to an embodiment, the ink IK may be a high viscosity ink. Accordingly, the settlement of the light-emitting elements ED supplied or dropped into the ink IK can become slower and the light-emitting elements ED can float longer in the ink IK in the subsequent process.

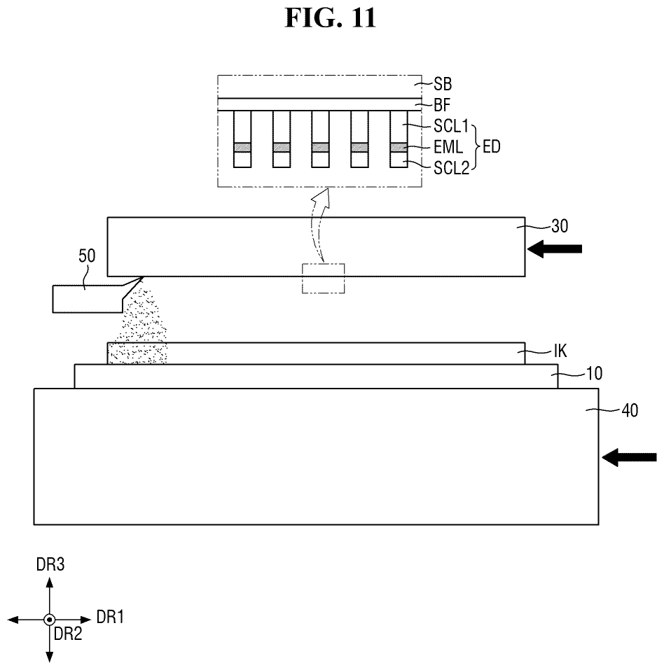

After supplying or applying the ink IK on the target substrate 10, the light-emitting elements ED may be supplied to the ink IK applied on the target substrate 10, as shown in FIG. 11. For example, the light-emitting element substrate 30 is placed above the target substrate 10 such that the light-emitting elements ED face the ink IK, and then the light-emitting elements ED may be separated from the semiconductor substrate SB to be dropped onto the ink IK on the target substrate 10.

According to an embodiment, the light-emitting elements ED may be separated from the semiconductor substrate SB using a cutting unit including a sharp object such as a knife 50, etc. For example, while transferring the stage 40 (or target substrate 10) and the light-emitting element substrate 30 (or semiconductor substrate SB) in the direction indicated by arrows shown in FIG. 11, the light-emitting element substrate may be scratched with the knife 50 to separate the light-emitting elements ED from the semiconductor substrate SB. According to an embodiment, by adjusting the transfer speed of the stage 40 (or target substrate 10) and the transfer speed of the light-emitting element substrate 30 (or semiconductor substrate SB), the number range and/or concentration of light-emitting elements ED supplied to each of the emission areas EMA can be appropriately adjusted. For example, by increasing the transfer speed of the stage 40 relative to the transfer speed of the light-emitting element substrate 30, the number range and/or concentration of the light-emitting elements ED supplied to each of the emission areas EMA of the target substrate 10 can be reduced. For example, by decreasing the transfer speed of the stage 40 relative to the transfer speed of the light-emitting element substrate 30, the number range and/or concentration of the light-emitting elements ED supplied to each of the emission areas EMA of the target substrate 10 may be increased.

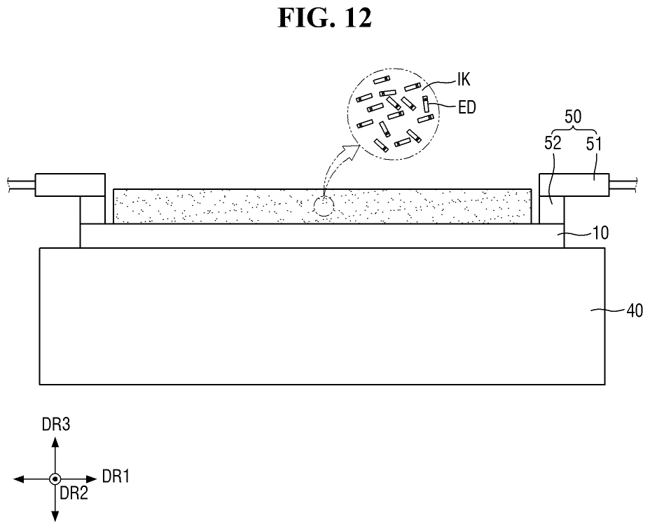

With the light-emitting elements ED supplied to the ink IK, an electric field may be applied to the light-emitting elements ED to align the light-emitting elements ED on the target substrate 10 as shown in FIG. 12. For example, a probe device 50 may be placed on pads of the target substrate 10 connected to the alignment electrodes ALE, and alignment signals may be applied to the alignment electrodes ALE through the probe device 50. The probe device 50 may include a probe jig 51 for transmitting an electrical signal to the target substrate 10, and a probe pad 52 in contact with pads of the target substrate 10 for transmitting an electrical signal to the target substrate 10. The probe jig 51 may be connected to a probe driver that generates or transmits electrical signals. The probe device 50 may be used to generate an electric field by applying an electrical signal to the target substrate 10, such as an alignment signal. According to the embodiments described herein, the device used to form an electric field on the target substrate 10 is not limited to the probe device 50. Other types or shapes of devices that can apply electric field may be used to apply alignment signals to the alignment electrodes ALE.

The alignment signal may be applied to the alignment electrodes ALE of the target substrate 10 while at least the light-emitting elements ED are supplied to the ink IK. Accordingly, the light-emitting elements ED may be aligned between the alignment electrodes ALE in the ink IK.

The timing for initiating application of the alignment signals may vary depending on embodiments. According to an embodiment, after supplying the light-emitting elements ED to the ink IK on the target substrate 10, an alignment signal may be applied to the alignment electrodes ALE. For example, the light-emitting elements ED may be supplied to the ink IK on the target substrate 10 while the alignment signal is being applied to the alignment electrodes ALE. As another example, after the alignment signal has been supplied or simultaneously with the supply of the alignment signal, the light-emitting elements ED may be supplied to the ink IK on the target substrate 10. The light-emitting elements ED may be aligned at appropriate positions (e.g., between the alignment electrodes ALE disposed in each of the emission areas EMA) by the electric field formed on the target substrate 10 while they settle in the ink IK and may be disposed on the target substrate 10. For example, the light-emitting elements ED may be disposed or attached directly on the target substrate 10 so that they are in contact with the fifth insulating layer 17 at the aligned positions.

According to the embodiments described herein, since the light-emitting elements ED are supplied and aligned after the ink IK has been supplied, it is possible to prevent or suppress the light-emitting elements ED from settling down in the ink IK before the light-emitting elements are placed or aligned at appropriate positions. Accordingly, the alignment of the light-emitting elements ED may be improved and the utilization efficiency of the light-emitting elements ED may be increased.

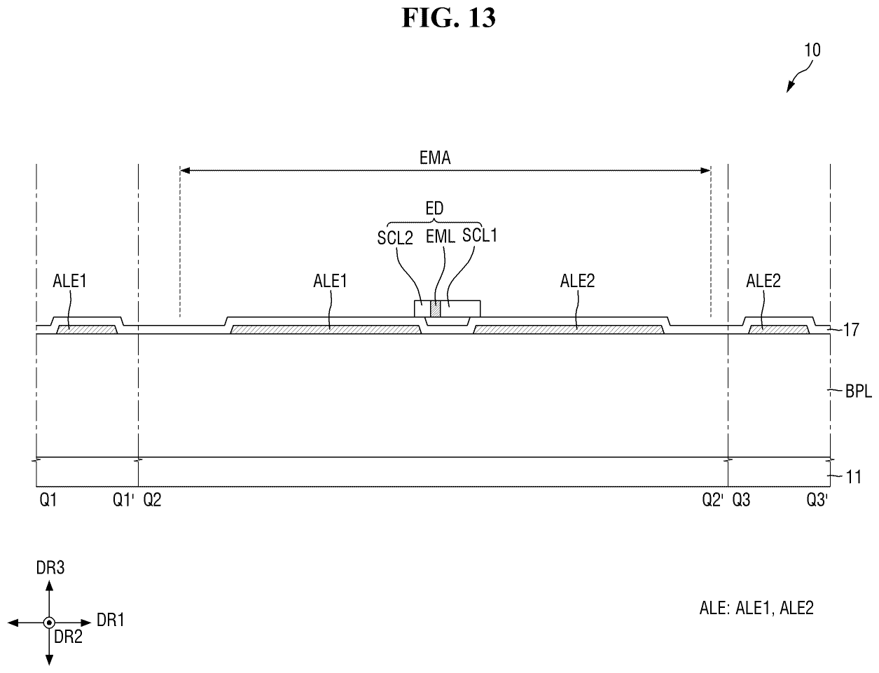

After the light-emitting elements ED have been aligned on the target substrate 10, the ink IK may be dried. Accordingly, as shown in FIG. 13, each of the light-emitting elements ED can be placed or fixed at the aligned position on the target substrate 10.

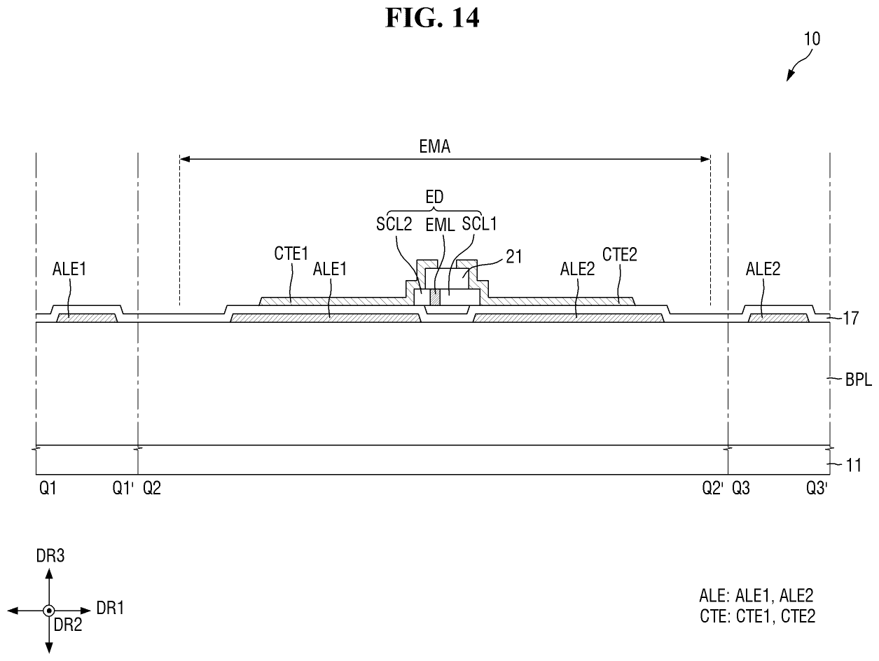

Subsequently, processes of fabricating pixels may be conducted after the light-emitting elements ED have been disposed. For example, as shown in FIG. 14, a sixth insulating layer 21 and contact electrodes CTE may be formed on the target substrate 10 on which the light-emitting elements ED are disposed. For the display device DD that does not include the sixth insulating layer 21, the contact electrodes CTE may be formed immediately after the light-emitting elements ED are disposed. The contact electrodes CTE may be formed on both ends of the light-emitting elements ED. For example, a first contact electrode CTE1 may be formed on the first ends of the light-emitting elements ED, and a second contact electrode CTE2 may be formed on the second ends of the light-emitting elements ED.

Subsequently, the seventh insulating layer 22 shown in FIG. 3, etc. may be formed. Accordingly, the display device DD according to embodiments may be fabricated.

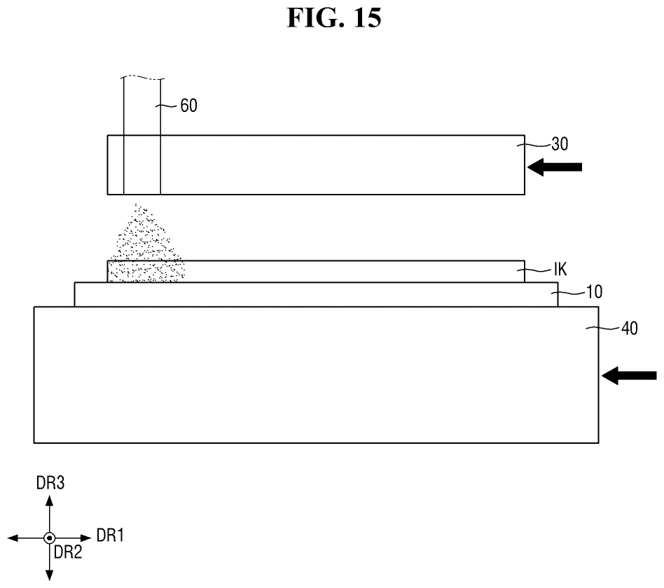

FIG. 15 is a cross-sectional view showing a method of fabricating a display device according to an embodiment. For example, FIG. 15 shows an embodiment that is different from the embodiment of FIG. 11 in a method and/or system for separating light-emitting elements ED from a semiconductor substrate SB.

Referring to FIG. 15 in addition to FIGS. 1 to 14, the light-emitting elements ED may be separated from the semiconductor substrate SB by irradiating the light-emitting element substrate 30 with a laser beam 60. For example, the light-emitting elements ED provided on the light-emitting element substrate 30 may be separated from the semiconductor substrate SB by performing a laser-induced forward transfer (LIFT) process or a laser lift-off (LLO) process using the laser beam 60, so that the light-emitting elements ED are dropped onto the ink IK on the target substrate 10. Except for the scheme for separating the light-emitting elements ED from the semiconductor substrate SB, the other processing steps may be performed in substantially the same or similar manner with the above-described embodiment; and, therefore, the redundant descriptions will be omitted for sake of brevity.

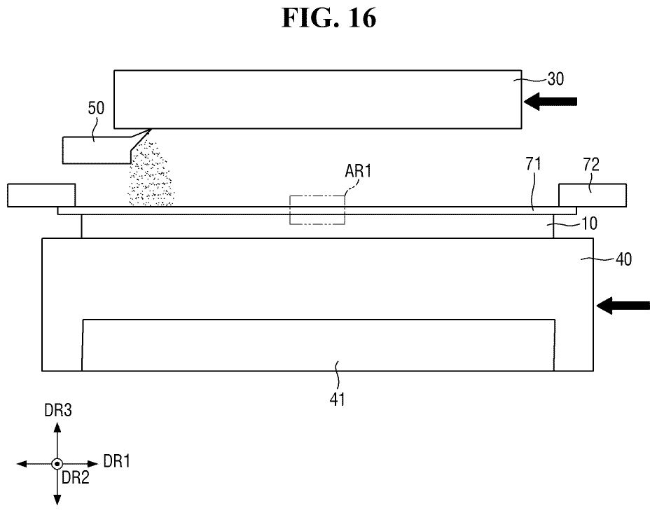

FIG. 16 is a cross-sectional view showing a method of fabricating a display device according to an embodiment. For example, FIG. 16 shows another embodiment in which a mask 71 is used to control the area where light-emitting elements ED are to be supplied.

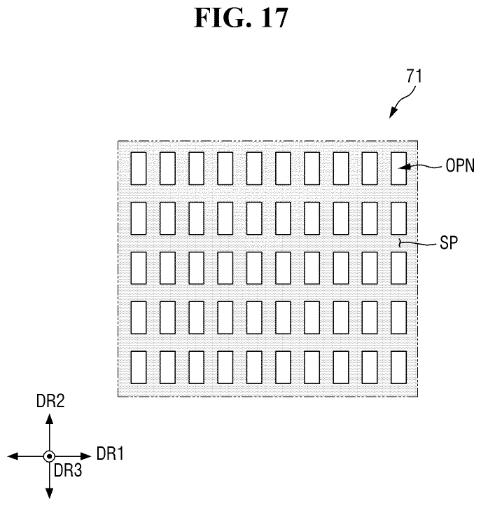

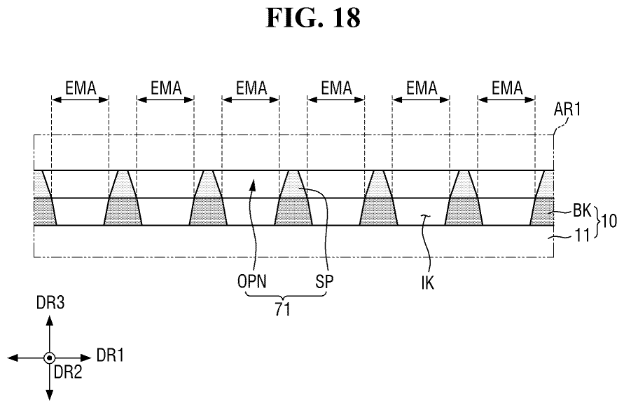

FIG. 17 is a plan view showing a mask 71 according to an embodiment. For example, FIG. 17 schematically shows a part of the mask 71 shown in FIG. 16. FIG. 18 is a cross-sectional view schematically showing area AR1 of FIG. 16.

Referring to FIGS. 16 to 18 in conjunction with FIGS. 1 to 15, the target substrate 10 may include a base substrate 11, and a bank BK disposed on the base substrate 11 to define emission areas EMA. The target substrate 10 may further include alignment electrodes ALE disposed in each of the emission areas EMA, as described above. In addition, the target substrate 10 may optionally further include a panel circuit layer BPL disposed between the base substrate 11 and the bank BK.

According to an embodiment, the mask 71 may include openings OPN associated with the emission areas EMA, and a screen pattern SP surrounding the openings OPN. Although the openings OPN have substantially the same size and shape in the example shown in FIG. 17, the embodiments are not limited thereto. For example, the size, shape or arrangement of the openings OPN may vary depending on the size, shape or arrangement of the emission areas EMA in the display area DPA.

According to an embodiment, light-emitting elements ED that emit lights of different colors may be sequentially supplied to the emission areas EMA of the pixels PX of different colors. In this instance, a plurality of masks 71 including openings OPN associated with the respective emission areas EMA where the light-emitting elements ED are to be supplied may be sequentially placed on the target substrate 10, and the light-emitting elements ED may be appropriately supplied to the emission areas EMA.

According to an embodiment, the mask 71 may include a metal pattern. As an example, the mask 71 may include a metal pattern forming the screen pattern SP. According to an embodiment, the mask 71 may be a fine metal mask (FMM) including fine openings OPN with a width for achieving the resolution of the display device DD, and a screen pattern SP.

According to an embodiment, the mask 71 may be connected or coupled to a mask frame 72. The mask frame 72 may support the mask 71 with a certain tension.

According to an embodiment, a mask holder 41 that pulls the mask 71 may be placed in the stage 40. Accordingly, the mask 71 may be stably placed or fixed on the target substrate 10. According to an embodiment, the mask holder 41 may include, but is not limited to, an electrostatic chuck or a magnetic chuck.

According to an embodiment, with the mask 71 disposed on the target substrate 10, the light-emitting elements ED may be supplied to the ink IK applied on the target substrate 10. For example, the mask 71 may be disposed on the target substrate 10 prior to supplying the light-emitting elements ED to the ink IK on the target substrate 10.

According to an embodiment, the mask 71 may be disposed on the bank BK of the target substrate 10. For example, the screen pattern SP of the mask 71 may be disposed on the bank BK, and the emission areas EMA may be exposed through the openings OPN of the mask 71. Accordingly, the light-emitting elements ED may be appropriately supplied to the emission areas EMA. By controlling the area where the light-emitting elements ED are supplied, it is possible to prevent the light-emitting elements ED from being supplied or placed in an unintended area (for example, the top of the bank BK, etc.), and to save the fabrication costs of the display device DD.

The mask 71 may be placed on the target substrate 10 before or after application of the ink IK. According to the embodiment described herein, after the mask 71 is placed on the target substrate 10, the ink IK and the light-emitting elements ED may be sequentially applied or supplied on the target substrate 10. Accordingly, it is possible to increase the use efficiency of the ink IK and the light-emitting elements ED by controlling the area where the ink IK and the light-emitting elements ED are supplied.

In another possible implementation, after the ink IK is applied on the target substrate 10, the mask 71 may be placed on the target substrate 10 applied with the ink IK, and the light-emitting elements ED may be supplied to the ink IK. For example, after the ink IK is applied to the emission areas EMA defined by the bank BK, the mask 71 may be placed on the bank BK and the light-emitting elements ED may be supplied to the ink IK.

According to the embodiment shown in FIG. 16, with the mask 71 placed on the target substrate 10, the light-emitting elements ED are separated from the semiconductor substrate SB using the knife 50 as in the embodiment of FIG. 11. It should be understood, however, that embodiments described hereinabove are not limited thereto. For example, with the mask 71 placed on the target substrate 10, the light-emitting elements ED may be separated from the semiconductor substrate SB using the laser beam 60 as in the embodiment of FIG. 15 or using other types of separating units or devices.

In concluding the detailed description, those skilled in the art will appreciate that many variations and modifications can be made to the embodiments without substantially departing from the principles of the invention. Therefore, the disclosed embodiments of the invention are used in a generic and descriptive sense only and not for purposes of limitation. The disclosure is defined by the following claims, with equivalents of the claims to be included therein.

What is claimed is:

1. A method of fabricating a display device, the method comprising:
preparing a target substrate and light-emitting elements;
applying ink on the target substrate;
supplying the light-emitting elements to the ink; and
aligning the light-emitting elements to aligned positions on the target substrate.

2. The method of claim 1, wherein the preparing the light-emitting elements comprises:
preparing a light-emitting element substrate comprising a semiconductor substrate and light-emitting elements formed in a rod shape on the semiconductor substrate, and
wherein the light-emitting elements are prepared to be connected to each other through the semiconductor substrate.

3. The method of claim 2, wherein the supplying the light-emitting elements to the ink comprises:
placing the light-emitting element substrate above the target substrate so that the light-emitting elements face the ink; and
separating the light-emitting elements from the semiconductor substrate and dropping them into the ink on the target substrate.

4. The method of claim 3, wherein the separating of the light-emitting elements from the semiconductor substrate comprises using a cutting unit comprising a knife to separate the light-emitting elements from the semiconductor substrate.

5. The method of claim 3, wherein the separating of the light-emitting elements from the semiconductor substrate comprises irradiating the light-emitting element substrate with a laser beam to separate the light-emitting elements from the semiconductor substrate.

6. The method of claim 1, wherein the ink is prepared without contacting the light-emitting elements and applied on the target substrate prior to the light-emitting elements.

7. The method of claim 1, wherein the target substrate comprises a base substrate and alignment electrodes disposed on the base substrate.

8. The method of claim 7, wherein the aligning of the light-emitting elements on the target substrate comprises applying an alignment signal to the alignment electrodes to align the light-emitting elements between the alignment electrodes.

9. The method of claim 8, wherein the alignment signal is applied to the alignment electrodes after the supplying of the light-emitting elements to the ink.

10. The method of claim 8, wherein the light-emitting elements are supplied to the ink while the alignment signal is being applied to the alignment electrodes.

11. The method of claim 1, wherein the target substrate comprises a base substrate and a bank disposed on the base substrate to define emission areas.

12. The method of claim 11, further comprising:
placing a mask comprising openings corresponding to the emission areas on the bank prior to the supplying of the light-emitting elements to the ink.

13. The method of claim 12, wherein the mask is placed on the target substrate prior to the applying of the ink on the target substrate.

14. The method of claim 12, wherein the mask is placed on the target substrate after the applying of the ink on the target substrate.

15. The method of claim 12, wherein the mask is fixed on the target substrate by placing a mask holder on a stage supporting the target substrate.

16. The method of claim 15, wherein
the mask comprises a metal pattern, and
the mask holder comprises an electrostatic chuck or a magnetic chuck.

17. The method of claim 1, further comprising:
after the aligning of the light-emitting elements on the target substrate, drying the ink to fix the light-emitting elements at the aligned positions.

18. The method of claim 17, further comprising:
forming a first contact electrode and a second contact electrode on both ends of the light-emitting elements, respectively.

19. A method of fabricating a display device, the method comprising:
preparing a target substrate comprising alignment electrodes;
preparing light-emitting elements formed on a semiconductor substrate;
applying ink on the target substrate;
supplying the light-emitting elements to the ink by separating the light-emitting elements from the semiconductor substrate above the target substrate; and
aligning the light-emitting elements to aligned positions on the target substrate.

20. The method of claim 19, wherein the separating of the light-emitting elements from the semiconductor substrate comprises using a cutting unit comprising a knife or a laser beam to separate the light-emitting elements from the semiconductor substrate.
